(19) United States
(12) Patent Application Publication
(10) Pub. No.: US 2026/0260683 A1
(43) Pub. Date: Sep. 3, 2026

(54) MEMORY DEVICE

(71) Applicant: KOREA ADVANCED INSTITUTE OF SCIENCE AND TECHNOLOGY, Daejeon (KR)

(72) Inventors: Seonghwan CHO, Daejeon (KR); Gi Woo LEE, Daejeon (KR); Donghwan KIM, Daejeon (KR)

(21) Appl. No.: 19/489,979

(22) PCT Filed: Apr. 5, 2024
(86) PCT No.: PCT/KR2024/004487

§ 371 Date: Dec. 4, 2025

(30) Foreign Application Priority Data
Jun. 9, 2023 (KR) 10-2023-0074044

(51) Int. Cl. G11C 11/4091; G11C 11/406; G11C 11/4093; G11C 11/4096

(52) U.S. Cl. CPC G11C 11/4091; G11C 11/406; G11C 11/4093; G11C 11/4096

(57) ABSTRACT

There is provided a memory device comprising: at least one memory cell array including word lines, bit lines, and memory cells; a plurality of sense amplifiers, each of which is configured to, in a read mode, convert each of first specific level voltages stored in each of the memory cells into each of first n-bit data and output them, and, in a write mode, convert second n-bit data into second specific level voltages so as to store them in each of the memory cells; and at least one MUX/DEMUX, each of which is configured to, in the read mode, multiplex each of the first significant bit values of f each of the k sense amplifiers to output k-bit output data, and in the write mode, demultiplex each of k-bit input data into each of second significant bit values and thus apply them to each of the k sense amplifiers.

### FIELD OF THE DISCLOSURE

The present disclosure relates to a memory device, and more specifically, the memory device that minimizes a time delay in reading and writing data in a memory cell for storing n-bit data and increases a density of the memory cell.

### BACKGROUND OF THE DISCLOSURE

A DRAM, a representative element in a semiconductor memory device, records data in a memory cell comprised of a single transistor and a single capacitor, and records a single bit of information, for example, a “0” or “1”, in the memory cell, by charging or discharging the capacitor.

Moreover, a multi-level DRAM has recently been proposed, which has increased data storage capacity by storing more than one bit of data in a single memory cell, other than storing the single bit of information, i.e., one bit information of “0” or “1”, in the memory cell including the single transistor and the single capacitor.

In addition, in the DRAM, a word line determines whether to access the capacitor by turning the transistor on or off, and data is stored in the capacitor or read from the capacitor through a bit line.

In such DRAM, a sense amplifier is used to read the data stored in the capacitor through the bit line. The sense amplifier reads the data stored in the memory cell by amplifying a voltage change of the bit line, which changes slightly due to a charge sharing between the capacitor and the bit line when the transistor is turned on by the word line.

However, in the conventional multi-level DRAM, n-bit data of the memory cell sensed through the sense amplifier is read, and then each of significant bit values in the n-bit data is transmitted to a MUX/DEMUX through each of different global input/output GIO lines. Herein, input/output may be indicated as I/O.

That is, by referring to the multi-level DRAM for storing 2-bit data in FIG. 1, each sense amplifier is connected to two global I/O lines in order to store the 2-bit data in the memory cell or in order to read the 2-bit data stored in the memory cell.

Therefore, the number of the memory cells that can be accessed in a single cycle through a single MUX/DEMUX that transmits and receives the data by using eight global I/O lines is limited to four depending on a prefetch size, and accordingly, a time delay occurs in reading and writing the data in a memory cell array.

Meanwhile, the sense amplifier for reading the n-bit data stored in the memory cell or writing the n-bit data in the memory cell includes an analog-to-digital converter, which senses a specific level voltage stored in the memory cell and thus converts it into the n-bit data, and a digital-to-analog converter, which converts the n-bit data into the specific level voltage and thus stores it in the memory cell. The analog-to-digital converter can be of two types: a flash analog-to-digital converter, which converts data in parallel, and a successive approximation register analog-to-digital converter, which converts data sequentially.

By referring to FIG. 1 again, when using the analog-to-digital converter that converts data in parallel, such as the flash analog-to-digital converter, eight bit values corresponding to four memory cells for storing the 2-bit data can be transmitted in a single cycle via eight global I/O lines, offering an advantage of reducing time delay required to access data in the memory cells. However, since data must be converted in parallel, separate comparators are required for each significant bit, which increases an area occupied by the analog-to-digital converter within the memory device.

Meanwhile, when using the analog-to-digital converter that converts data sequentially, such as the successive approximation register analog-to-digital converter, there is an advantage in that the area within the memory device does not increase significantly compared to the analog-to-digital converter that converts data in parallel, since the number of comparators required for data conversion does not increase. However, by sequentially converting the data, there is a problem that a time delay occurs in accessing the data in the memory cells because one cycle is required to transmit the most significant bit (MSB) and another cycle is required to transmit the least significant bit (LSB), i. e., a total of two cycles, for each of the four memory cells.

### DETAILED EXPLANATION OF THE DISCLOSURE

### Objects of the Invention

It is an object of the present disclosure to solve all the aforementioned problems.

It is another object of the present disclosure to minimize a time delay for data access in memory cells storing n-bit data.

It is still another object of the present disclosure to increase a density of the memory cells storing the n-bit data.

It is still yet another object of the present disclosure to enable efficient data transmission in the memory cells storing the n-bit data.

### Means of Solving the Problem

In accordance with one aspect of the present disclosure to accomplish objects above, there is provided a memory device comprising a plurality of memory cells storing n-bit data by an operation of a plurality of word lines and a plurality of bit lines, comprising: at least one memory cell array including the plurality of word lines, the plurality of bit lines, and the plurality of memory cells; a plurality of sense amplifiers, each of which is coupled to each of the plurality of bit lines, wherein each of the plurality of sense amplifiers is configured to, in a read mode, convert each of first specific level voltages stored in each of the plurality of memory cells into each of first n-bit data and output each of the first n-bit data, wherein each of first significant bit values of each of the first n-bit data is sequentially outputted, and wherein n is an integer of 2 or more, and, in a write mode, convert second n-bit data into second specific level voltages so as to store the second specific level voltages in each of the plurality of memory cells; and at least one MUX/DEMUX, wherein each of k global I/O lines corresponding to a prefetch size is coupled to each of k sense amplifiers in each of sense amplifier groups, wherein the sense amplifier groups are obtained by grouping the plurality of sense amplifiers by k, wherein k is an integer of 1 or more, wherein the at least one MUX/DEMUX is configured to, in the read mode, multiplex each of the first significant bit values of each of the k sense amplifiers to output k-bit output data, and in the write mode, demultiplex each of k-bit input data into each of second significant bit values and thus apply each of the second significant bit values to each of the k sense amplifiers through each of the k global I/O lines.

As one example, (R) in the read mode, (R_1) in a (1_1)-st cycle, each of the k sense amplifiers, which is a first sense amplifier to a k-th sense amplifier, outputs a (1_1_1)-st significant bit value of a (1_1)-st n-bit data to a (1_k_1)-st significant bit value of a (1_k)-th n-bit data, wherein each of the (1_1_1)-st significant bit value (1_k_1)-st significant bit value corresponds to each of a (1_1)-st specific level voltage to a (1_k)-th specific level voltage stored in each of a first memory cell to a k-th memory cell corresponding to each of the first sense amplifier to the k-th sense amplifier, (R_2) in a (1_i)-th cycle, each of the first sense amplifier to the k-th sense amplifier outputs each of a (1_1_i)-th significant bit value of the (1_1)-th n-bit data to a (1_k_i)-th significant bit value of the (1_k)-th n-bit data, and the MUX/DEMUX multiplexes a (1_1_(i−1))-th significant bit value to a (1_k_(i−1))-th significant bit value transmitted through each of a first global I/O line to a k-th global I/O line and thus outputs a (i−1)-th k-bit output data comprised of the (1_1_(i−1))-th significant bit value to the (1_k_(i−1)-th significant bit value, wherein i is an integer increasing from 2 to n, (R_3) in a (1_(n+1)-th cycle, the MUX/DEMUX multiplexes a (1_1_n)-th significant bit value to a (1_k_n)-th significant bit value transmitted through each of the first global I/O line to the k-th global I/O line and thus outputs an n-th k-bit output data comprised of the (1_1_n)-th significant bit value to the (1_k_n)-th significant bit value, and wherein, (W) in the write mode, (W_1) in a (2_1)-st cycle, the MUX/DEMUX demultiplexes a first k-bit input data and thus outputs each of a (2_1_1)-st significant bit value to a (2_k_1)-st significant bit value through each of the first global I/O line to the k-th global I/O line, (W_2) in a (2_i)-th cycle, the MUX/DEMUX demultiplexes an i-th k-bit input data and thus outputs each of a (2_1_i)-th significant bit value to a (2_k_i)-th significant bit value through each of the first global I/O line to the k-th global I/O line, and each of the first sense amplifier to the k-th sense amplifier latches each of a (2_1_(i−1)-th significant bit value to a (2_k_(1−1)-th significant bit value transmitted through each of the first global I/O line to the k-th global I/O line, (W_3) in a (2_(n+1)-th cycle, each of the first sense amplifier to the k-th sense amplifier latches each of a (2_1_n)-th significant bit value to a (2_k_n)-th significant bit value transmitted through each of the first global I/O line to the k-th global I/O line, and stores each of a (2_1)-st specific level voltage to a (2_k)-th specific level voltage corresponding to each of a (2_1)-st n-bit data to a (2_k)-th n-bit data in each of the first memory cell to the k-th memory cell, wherein the (2_1)-st n-bit data is comprised of a latched (2_1_1)-st significant bit value to a latched (2_1_n)-th significant bit value, and wherein the (2_k)-th n-bit data is comprised of a latched (2_k_1)-st significant bit value to a latched (2_k_n)-th significant bit value.

As one example, each of a first bit line to a k-th bit line coupled to each of the k sense amplifiers is located in a same memory cell array, wherein each of the k sense amplifiers is coupled to each of the k global I/O lines coupled to one of the MUX/DEMUX.

As one example, each of a first bit line to a k-th bit line coupled to each of the k sense amplifiers is located in a different memory cell array, wherein each of the k sense amplifiers is coupled to each of the k global I/O lines of each of the MUX/DEMUX.

As one example, each of the k sense amplifiers includes each of successive approximation register analog-to-digital converters that sequentially outputs each of the first significant bit values of each of the first n-bit data.

As one example, each of the k sense amplifiers includes each of input ends into which each of the second significant bit values is inputted, each of selection switches that sequentially activates each of the input ends, and each of digital-to-analog converters that applies, to each of the plurality of bit lines, each of the second specific level voltages corresponding to each of the second significant bit values sequentially inputted through each of the selection switches.

As one example, each of the k sense amplifiers refreshes each of k memory cells corresponding to each of the k sense amplifiers by using at least some of specific significant bit values among the first significant bit values.

As one example, each of the k sense amplifiers is coupled to the k global I/O lines through each of k global switches, wherein each of the k global switches is deactivated when each of the specific significant bit values are used to refresh each of the k memory cells.

### Effects of the Invention

According to the present disclosure, the following effects are achieved.

The present disclosure has an effect of minimizing a time delay for data access in memory cells storing n-bit data.

The present disclosure has another effect of increasing a density of the memory cells storing the n-bit data.

The present disclosure has still another effect of enabling efficient data transmission in the memory cells storing the n-bit data.

### BRIEF DESCRIPTION OF THE DRAWINGS

FIG. 1 is a drawing schematically illustrating a conventional memory device including a memory cell storing 2-bit data.

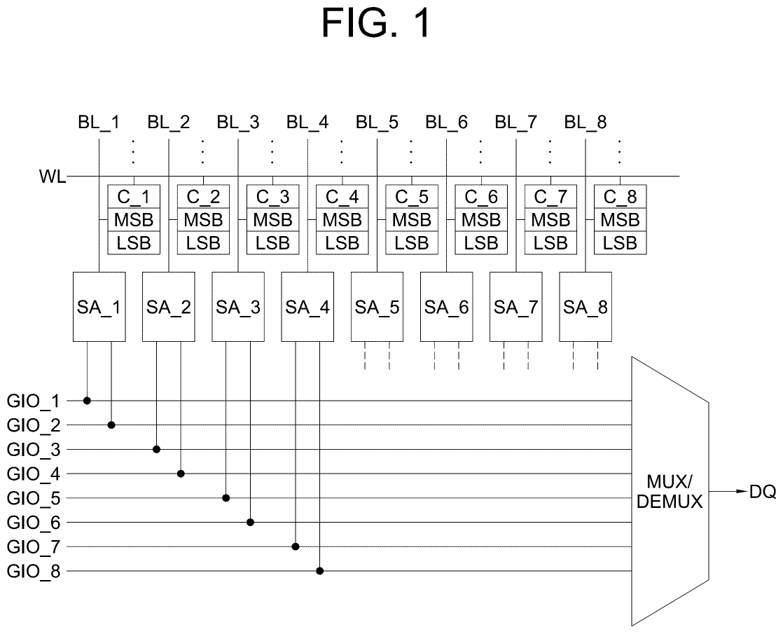

FIG. 2 is a drawing schematically illustrating a memory device including a memory cell storing 2-bit data in accordance with one example embodiment of the present disclosure.

FIG. 3 is a drawing schematically illustrating a sense amplifier in the memory device in accordance with one example embodiment of the present disclosure.

FIG. 4 is a drawing schematically illustrating an analog-to-digital converter of the sense amplifier in the memory device in accordance with one example embodiment of the present disclosure.

FIG. 5 is a drawing schematically illustrating another configuration of global I/O line in the memory device in accordance with one example embodiment of the present disclosure.

FIG. 6 is a drawing schematically illustrating a read mode for reading data in the memory device in accordance with one example embodiment of the present disclosure.

FIG. 7 is a drawing schematically illustrating a write mode for writing the data in the memory device in accordance with one example embodiment of the present disclosure.

### DETAILED DESCRIPTION OF THE PREFERRED EMBODIMENTS

Detailed explanation on the present disclosure to be made below refer to attached drawings illustrated as specific embodiment examples under which the present disclosure may be implemented. These embodiments are described in sufficient detail to enable those skilled in the art to practice the disclosure. It is to be understood that the various embodiments of the present disclosure, although different, are not necessarily mutually exclusive. For example, a particular feature, structure, or characteristic described herein in connection with one embodiment may be implemented within other embodiments without departing from the spirit and scope of the present disclosure. In addition, it is to be understood that the position or arrangement of individual elements within each disclosed embodiment may be modified without departing from the spirit and scope of the present disclosure. The following detailed description is, therefore, not to be taken in a limiting sense, and the scope of the present disclosure is defined only by the appended claims, appropriately interpreted, along with the full range of equivalents to which the claims are entitled. In the drawings, like numerals refer to the same or similar functionality throughout the several views.

To allow those skilled in the art to the present disclosure to be carried out easily, the example embodiments of the present disclosure by referring to attached drawings will be explained in detail as shown below. A memory device according to the present disclosure may be any one of random access memories (RAM) including DRAM (Dynamic Random Access Memory), SDRAM (Synchronous DRAM), SRAM (Static RAM), DDR SDRAM (Double Date Rate SDRAM), DDR2 SDRAM, DDR3 SDRAM, PRAM (Phase-change RAM), MRAM (Magnetic RAM), RRAM (Resistive RAM), etc., and the following description will focus on DRAM. In addition, although a memory cell includes a switch element that is switched by a word line signal and a cell capacitor that stores a charge, for the convenience of description, the cell capacitor may be referred to as the memory cell.

In addition, for the convenience of description, the present disclosure will be described in detail by using drawings created based on 2-bit data in the memory cell, but the present disclosure is not limited to the drawings. In addition, for the convenience of description, the drawings only illustrate a single MUX/DEMUX having eight memory cells, eight sense amplifiers, and eight global I/O lines, however, the present disclosure is not limited thereto.

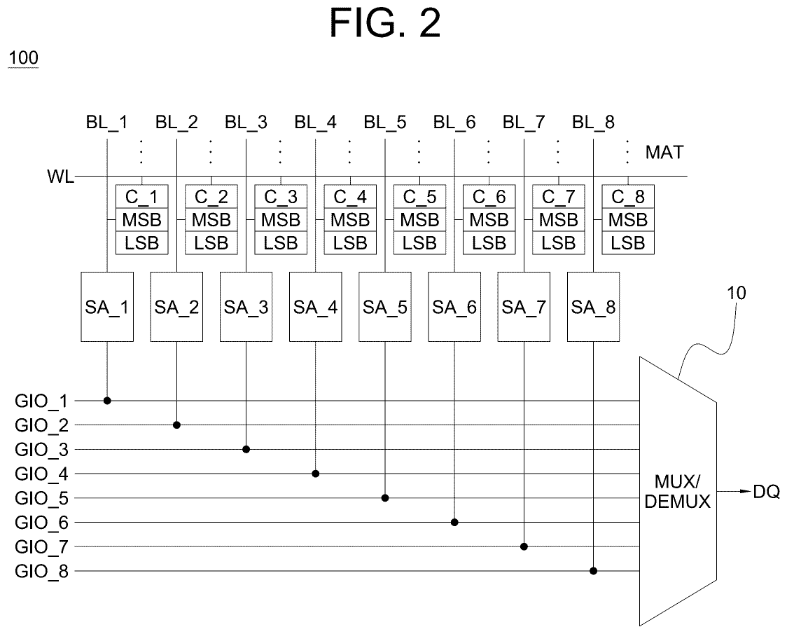

FIG. 2 is a drawing schematically illustrating the memory device including the memory cell storing 2-bit data in accordance with one example embodiment of the present disclosure.

The memory device in accordance with one example embodiment of the present disclosure may include at least one memory cell array including a plurality of word lines, a plurality of bit lines, and a plurality of memory cells. Herein, each of the plurality of memory cells may store each of specific level voltages corresponding to n-bit data, and may be turned on to perform a charge sharing with each of corresponding bit lines as corresponding specific word line is activated by a row address. The n may be an integer of 2 or more.

For example, by referring to FIG. 2, one memory cell array MAT in the memory device 100 in accordance with one example embodiment of the present disclosure is illustrated, and eight memory cells C_1, C_2, . . . , C_8 that are turned on according to an activation of the specific word line WL, and eight bit lines BL_1, BL_2, . . . , BL_8 connected to each of the eight memory cells C_1, C_2, . . . , C_8 Are Illustrated. Accordingly, in the Memory device 100 of the present disclosure, the specific word line WL is activated by the row address, and accordingly, the eight memory cells C_1, C_2, . . . , C_8 coupled to the specific word line WL are turned on, and each of the eight turned-on memory cells C_1, C_2, . . . , C_8 may perform the charge sharing with each of the eight bit lines BL_1, BL_2, . . . , BL_8.

In addition, the memory device in accordance with one example embodiment of the present disclosure may include a plurality of sense amplifiers, each of which is coupled to each of the plurality of bit lines, wherein each of the plurality of sense amplifiers is configured to, in a read mode, convert each of first specific level voltages stored in each of the plurality of memory cells into each of first n-bit data and output each of the first n-bit data, wherein each of first significant bit values of each of the first n-bit data is sequentially outputted, and, in a write mode, convert second n-bit data into second specific level voltages so as to store the second specific level voltages in each of the plurality of memory cells.

For example, by referring to FIG. 2, eight sense amplifiers SA_1, SA_2, . . . , SA_8 are illustrated, and accordingly, each of the eight sense amplifiers SA_1, SA_2, . . . , SA_8 of the memory device 100 in accordance with one example embodiment of the present disclosure may be coupled to each of the eight bit lines BL_1, BL_2, . . . , BL_8. Herein, each of the eight sense amplifiers SA_1, SA_2, . . . , SA_8 may be activated by a column address in the read mode of the memory device 100, and convert each of eight first specific level voltages stored in each of the eight memory cells C_1, C_2, . . . , C_8 through each of the eight bit lines BL_1, BL_2, . . . , BL_8 into each of eight first n-bit data and output each of the eight first n-bit data, wherein each of the first significant bit values of each of the eight first n-bit data is sequentially outputted. That is, each of the eight sense amplifiers SA_1, SA_2, . . . , SA_8 may sequentially output eight first significant bit values to eight n-th significant bit values from each of the eight first n-bit data. Herein, the first to n-th significance may refer to an MSB (Most Significant Bit) to an LSB (Least Significant Bit) in the n-bit data, or the LSB (Least Significant Bit) to the MSB (Most Significant Bit) in the n-bit data. Also, each of the eight sense amplifiers SA_1, SA_2, . . . , SA_8 may be activated by the column address in the write mode of the memory device 100, convert each of eight second n-bit data into each of eight second specific level voltages, and store each of the eight second specific level voltages in each of the eight memory cells C_1, C_2, . . . , C_8 through each of the eight bit lines BL_1, BL_2, . . . , BL_8.

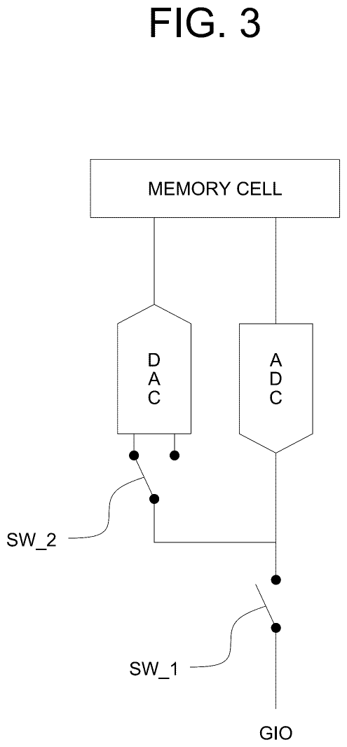

Herein, by referring to FIG. 3, each of the plurality of sense amplifiers may include an analog-to-digital converter ADC that converts the specific level voltage stored in the memory cell into the n-bit data in the read mode and a digital-to-analog converter DAC that converts the n-bit data into the specific level voltage in the write mode and thus stores it in the memory cell. Also, the digital-to-analog converter DAC may sequentially receive each of significant bit values of the n-bit data through a single input end, and latch or buffer each of the inputted significant bit values and then convert them to the specific level voltage when all significant bit values are received, or the digital-to-analog converter DAC may be provided with the input ends into which each of the significant bit values is inputted, receive each of the significant bit values through a selection switch SW_2 that sequentially activates the input ends, and latch or buffer each of the inputted significant bit values and then convert them to the specific level voltage when all significant bit values are received. Meanwhile, a switch SW_1 will be described later.

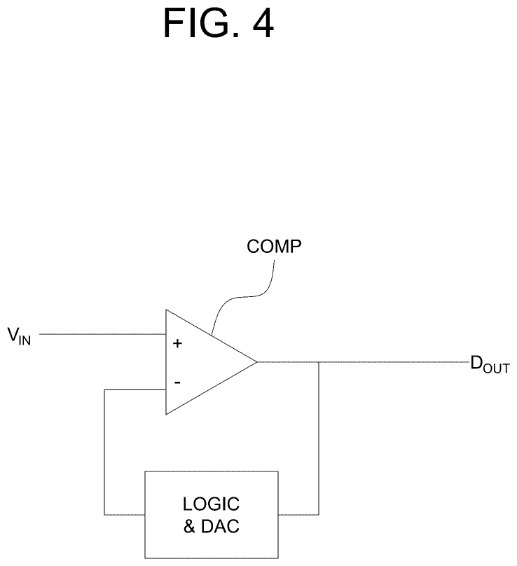

Moreover, by referring to FIG. 4, the analog-to-digital converter ADC included in each of the plurality of sense amplifiers may be configured as a successive approximation register analog-to-digital converter that converts the specific level voltage stored in the memory cell into the n-bit data by using a single comparator comp, and sequentially outputs each of the significant bit values of the n-bit data.

Also, the memory device in accordance with one example embodiment of the present disclosure may include at least one MUX/DEMUX, wherein each of k global I/O lines corresponding to a prefetch size is coupled to each of k sense amplifiers in each of sense amplifier groups, wherein the sense amplifier groups are obtained by grouping the plurality of sense amplifiers by k. The k may be an integer of 1 or more.

For example, by referring to FIG. 2, a case where k is 8 is illustrated, and accordingly, the memory device 100 in accordance with one example embodiment of the present disclosure may include at least one MUX/DEMUX 10, wherein each of eight global I/O lines GIO_1, GIO_2, . . . , GIO_8 corresponding to the prefetch size is coupled to each of the eight sense amplifiers SA_1, SA_2, . . . , SA_8 included in one sense amplifier group.

Also, the MUX/DEMUX in the memory device in accordance with one example embodiment of the present disclosure may be configured to, in the read mode, multiplex each of the first significant bit values of each of the k sense amplifiers to output k-bit output data, and in the write mode, demultiplex each of k-bit input data into each of second significant bit values and thus apply each of the second significant bit values to each of the k sense amplifiers through each of the k global I/O lines.

For example, by referring to FIG. 2, in the read mode of the memory device 100, in a specific cycle in a continuous cycle, which is a time from when the memory cell is accessed once until the next access begins, the MUX/DEMUX 10 in the memory device in accordance with one example embodiment of the present disclosure may multiplex eight specific significant bit values outputted from each of the eight sense amplifiers SA_1, SA_2, . . . , SA_8 and thus output one 8-bit output data. In addition, in the write mode of the memory device 100, in the specific cycle, the MUX/DEMUX 10 in the memory device in accordance with one example embodiment of the present disclosure may demultiplex 8-bit input data and thus generate the eight specific significant bit values, and then input each of the eight specific significant bit values into each of the eight sense amplifiers SA_1, SA_2, . . . , SA_8.

Herein, in the memory device in accordance with one example embodiment of the present disclosure, each of the k sense amplifiers may be coupled to each of the k global I/O lines coupled to one MUX/DEMUX, and each of k bit lines, i.e., a first bit line to a k-th bit line, coupled to each of the k sense amplifiers may be located in a same memory cell array. However, the present disclosure is not limited thereto, and each of the k bit lines may be located in a different memory cell array.

For example, by referring to FIG. 2, in the memory device 100 in accordance with one example embodiment of the present disclosure, each of the eight sense amplifiers SA_1, SA_2, . . . , SA_8 included in one sense amplifier group may be coupled to each of the eight global I/O lines GIO_1, GIO_2, . . . , GIO_8 of the MUX/DEMUX 10. In addition, each of the first bit line BL_1 to the eighth bit line BL_8 coupled to each of the eight sense amplifiers SA_1, SA_2, . . . , SA_8 may be located in the same memory cell array MAT. Herein, the first bit line BL_1 to the eighth bit line BL_8 may be arranged at consecutive locations within the same memory cell array MAT, or at least some of the first bit line BL_1 to the eighth bit line BL_8 may be arranged at non-consecutive Locations.

In addition, in the memory device in accordance with one example embodiment of the present disclosure, each of the k sense amplifiers may be coupled to each of the k global I/O lines of each of the MUX/DEMUX, and each of the first bit line to the k-th bit line coupled to each of the k sense amplifiers may be located in a different memory cell array. However, the present disclosure is not limited thereto, and each of the k bit lines may be located in the same memory cell array.

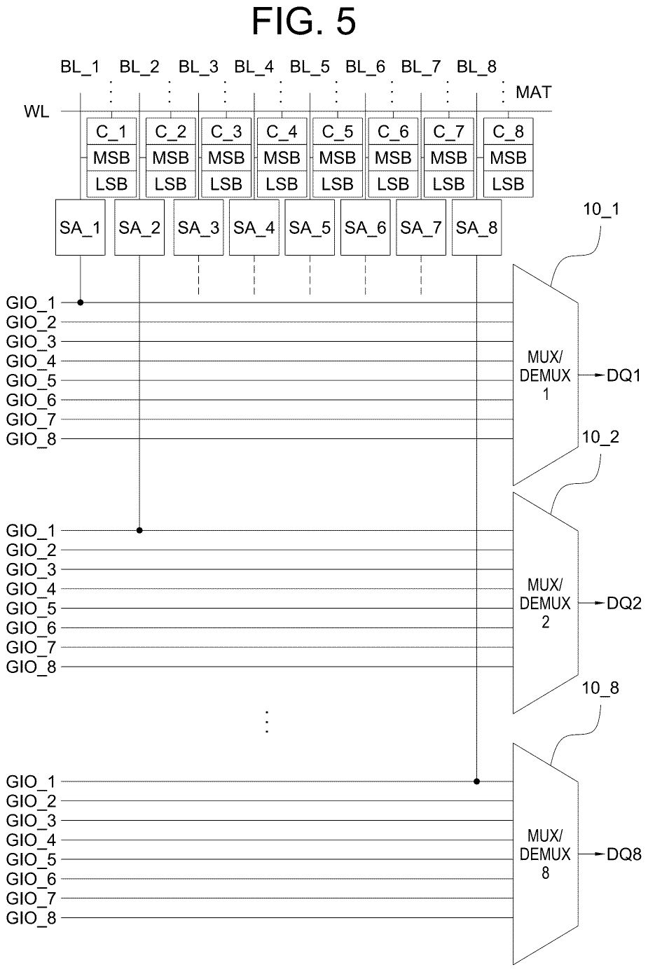

For example, by referring to FIG. 5, in the memory device 100 in accordance with one example embodiment of the present disclosure, each of the eight sense amplifiers SA_1, SA_2, . . . , SA_8, i.e., the first sense amplifier SA_1 to the eighth sense amplifier SA_8, included in one sense amplifier group may be coupled to each of the first global I/O lines GIO_1 of each of eight MUX/DEMUX 10_1, 10_2, . . . , 10_8, i.e., a first MUX/DEMUX 10_1 to an eighth MUX/DEMUX 10_8. Herein, it is illustrated that each of the first sense amplifier SA_1 to the eight sense amplifier SA_8 is coupled to the first global I/O lines GIO_1 of each of the first MUX/DEMUX 10_1 to the eighth MUX/DEMUX 10_8, but the present disclosure is not limited thereto, and each of the first sense amplifier SA_1 to the eight sense amplifier SA_8 may be coupled to different significant global I/O lines of each of the first MUX/DEMUX 10_1 to the eighth MUX/DEMUX 10_8. In addition, in FIG. 5, it is illustrated that each of the first bit line BL_1 to the eighth bit line BL_8 coupled to each of the first sense amplifier SA_1 to the eight sense amplifier SA_8 is arranged at consecutive locations within the same memory cell array MAT, but the present disclosure is not limited thereto, and at least some of the first bit line BL_1 to the eighth bit line BL_8 may be arranged at non-consecutive locations within the same memory cell array MAT. In addition, at least some of the first bit line BL_1 to the eighth bit line BL_8 may be arranged in different memory cell arrays MAT.

An operation in the read mode for reading the n-bit data stored in the memory cell in the memory device in accordance with one example embodiment of the present disclosure is described as follows.

The specific word line is activated by the row address, and accordingly, the memory cells coupled to the specific word line are turned on, and each of the turned-on memory cells may perform the charge sharing with each of the coupled bit lines.

In addition, in a (1_1)-st cycle, which is a first cycle to read the n-bit data stored in the memory cells, according to the column address, each of the k sense amplifiers, i.e., a first sense amplifier to a k-th sense amplifier, may output a (1_1_1)-st significant bit value of a (1_1)-st n-bit data to a (1_k_1)-st significant bit value of a (1_k)-th n-bit data, wherein each of the (1_1_1)-st significant bit value to the (1_k_1)-st significant bit value corresponds to each of a (1_1)-st specific level voltage to a (1_k)-th specific level voltage stored in each of a first memory cell to a k-th memory cell corresponding to each of the first sense amplifier to the k-th sense amplifier.

Then, in a (1_i)-th cycle, each of the first sense amplifier to the k-th sense amplifier may output each of a (1_1_i)-th significant bit value of the (1_1)-th n-bit data to a (1_k_i)-th significant bit value of the (1_k)-th n-bit data. The i may be an integer increasing from 2 to n. At the same time, the MUX/DEMUX may multiplex a (1_1_(i−1)-th significant bit value to a (1_k_(i−1)-th significant bit value transmitted through each of a first global I/O line to a k-th global I/O line and thus output a (i−1)-th k-bit output data comprised of the (1_1_(i−1)-th significant bit value to the (1_k_(i−1)-th significant bit value.

In addition, in a (1_(n+1)-th cycle, the MUX/DEMUX may multiplex a (1_1_n)-th significant bit value to a (1_k_n)-th significant bit value transmitted through each of the first global I/O line to the k-th global I/O line and thus output an n-th k-bit output data comprised of the (1_1_n)-th significant bit value to the (1_k_n)-th significant bit value.

That is, the memory device in accordance with one example embodiment of the present disclosure may read k n-bit data recorded in the k memory cells as n k-bit data comprised of each of significant bit values.

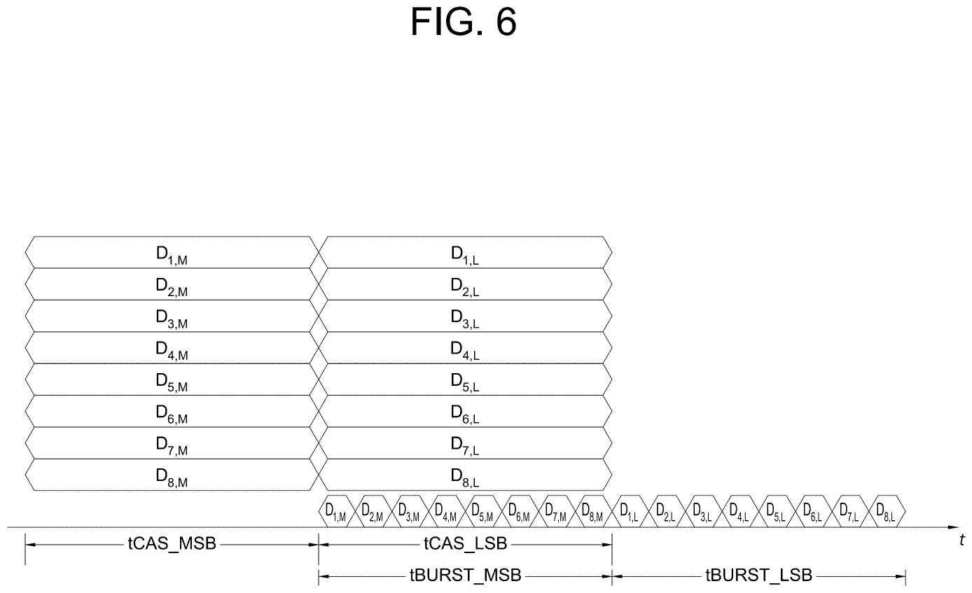

An operation of reading in the memory device in accordance with one example embodiment of the present disclosure may be illustrated based on FIGS. 2 and 2-bit data of FIG. 6 as follows. Herein, the memory device is exemplified as outputting the 8-bit output data according to the prefetch size.

As the specific word line WL is activated by the row address, each of the first memory cell C_1 to the eighth memory cell C_8 may be turned on to perform the charge sharing with each of the first bit line BL_1 to the eighth bit line BL_8.

In addition, in a first cycle tCAS_MSB, according to the column address, each of the first sense amplifier SA_1 to the eighth sense amplifier SA_8 may sense each of the first specific level voltage to an eighth specific level voltage stored in each of the first memory cell C_1 to the eighth memory cell C_8 through each of the first bit line BL_1 to the eighth bit line BL_8, and thus output each of a first most significant bit value D_{1,M} in first 2-bit data corresponding to the first specific level voltage to an eighth most significant bit value D_{8,M} in eighth 2-bit data corresponding to the eighth specific level voltage.

Then, in a second cycle tCAS_LSB=tBUSRT_MSB, each of the first sense amplifier SA_1 to the eighth sense amplifier SA_8 may output each of a first least significant bit value D_{1,L} in the first 2-bit data corresponding to the first specific level voltage to an eighth least significant bit value D_{8,L} in the eighth 2-bit data corresponding to the eighth specific level voltage.

At the same time, the MUX/DEMUX 10 may multiplex the first most significant bit value D_{1,M} from the first sense amplifier SA_1 to the eighth most significant bit value D_{8,M} from the eighth sense amplifier SA_8 transmitted in parallel through the first global I/O line GIO_1 to the eighth global I/O line GIO_8, and thus output first 8-bit output data comprised of the first most significant bit value D_{1,M} to the eighth most significant bit value D_{8,M}.

In addition, in a third cycle tBURST_LSB, the MUX/DEMUX 10 may multiplex the first least significant bit value D_{1,L} from the first sense amplifier SA_1 to the eighth least significant bit value D_{8,L} from the eighth sense amplifier SA_8 transmitted in parallel through the first global I/O line GIO_1 to the eighth global I/O line GIO_8, and thus output second 8-bit output data comprised of the first least significant bit value D_{1,L} to the eighth least significant bit value D_{8,L}.

Meanwhile, both the most significant bit values and the least significant values are used as data of the memory device in the above, but some significant bit values may be used as data of the memory device and some significant bit values may be used for refresh.

For example, as shown in FIG. 3, when a global switch SW_1 is installed between the sense amplifier and the global I/O line, the global switch SW_1 may be activated to thereby transmit the most significant bit value to the MUX/DEMUX, and the global switch SW_1 may be deactivated for refresh to thereby transmit the least significant bit value to the digital-to-analog converter. Herein, the digital-to-analog converter may replicate the inputted least significant bit value and store the specific level voltage corresponding to the 2-bit data in the memory cell.

Meanwhile, in the above, the digital-to-analog converter replicates the inputted least significant bit value so that the specific level voltage corresponding to the 2-bit data may be stored in the memory cell, however, in contrast, the global switch SW_1 may be activated to thereby transmit the most significant bit value to the MUX/DEMUX while the most significant bit value is inputted to the digital-to-analog converter so that the digital-to-analog converter latches the most significant bit value, and the global switch SW_1 may be deactivated for refresh to thereby transmit the least significant bit value only to the digital-to-analog converter, so that the digital-to-analog converter latches the least significant bit value, and thus the specific level voltage corresponding to the 2-bit data comprised of the latched most significant bit value and the latched least significant bit value may be stored in the memory cell.

Also, an operation in the write mode for writing the n-bit data in the memory cell in the memory device in accordance with one example embodiment of the present disclosure is described as follows.

The specific word line may be activated by the row address, and accordingly, the memory cells coupled to the specific word line may be turned on.

In addition, in a (2_1)-st cycle, which is a first cycle to write the second n-bit data in the memory cells, the MUX/DEMUX may demultiplex a first k-bit input data and thus output each of a (2_1_1)-st significant bit value to a (2_k_1)-st significant bit value through each of the first global I/O line to the k-th global I/O line.

Then, in a (2_i)-th cycle, the MUX/DEMUX may demultiplex an i-th k-bit input data and thus output each of a (2_1_i)-th significant bit value to a (2_k_i)-th significant bit value through each of the first global I/O line to the k-th global I/O line. At the same time, each of the first sense amplifier to the k-th sense amplifier may latch each of a (2_1_(i−1)-th significant bit value to a (2_k_(i−1)-th significant bit value transmitted through each of the first global I/O line to the k-th global I/O line.

In addition, in a (2_(n+1))-th cycle, each of the first sense amplifier to the k-th sense amplifier may latch each of a (2_1_n)-th significant bit value to a (2_k_n)-th significant bit value transmitted through each of the first global I/O line to the k-th global I/O line, and store each of a (2_1)-st specific level voltage to a (2_k)-th specific level voltage corresponding to each of a (2_1)-st n-bit data to a (2_k)-th n-bit data in each of the first memory cell to the k-th memory cell, wherein the (2_1)-st n-bit data is comprised of a latched (2_1_1)-st significant bit value to a latched (2_1_n)-th significant bit value, and wherein the (2_k)-th n-bit data is comprised of a latched (2_k_1)-st significant bit value to a latched (2_k_n)-th significant bit value.

That is, the memory device in accordance with one example embodiment of the present disclosure may generate the k n-bit data by using each of the significant bit values from n k-bit input data, and record each of the n-bit data in the k memory cells.

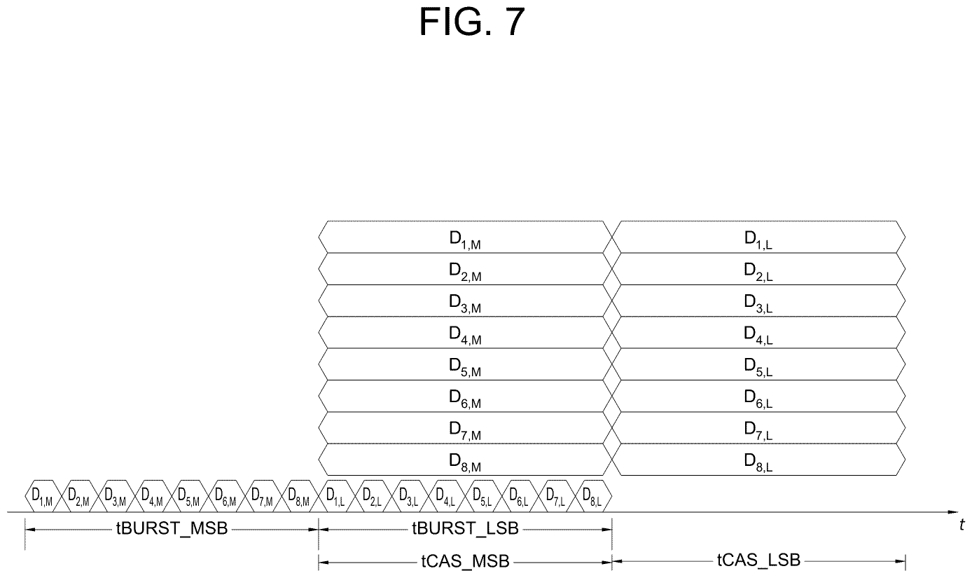

An operation of writing in the memory device in accordance with one example embodiment of the present disclosure may be illustrated based on FIG. 2 and the 2-bit data of FIG. 7 as follows. Herein, the memory device is exemplified as recording the 8-bit input data according to the prefetch size.

As the specific word line WL is activated by the row address, the first memory cell C_1 to the eighth memory cell C_8 coupled to the specific word line WL may be turned on.

In addition, in a first cycle tBURST_MSB, according to the column address, the MUX/DEMUX 10 may demultiplex the inputted first 8-bit input data to thereby generate the first most significant bit value D_{1,M} to the eighth most significant bit value D_{8,M}, and transmit each of the first most significant bit value D_{1,M} to the eighth most significant bit value D_{8,M} through each of the first global I/O line GIO_1 to the eighth global I/O line GIO_8.

Then, in a second cycle tBURST_LSB=tCAS_MSB, the MUX/DEMUX may demultiplex the inputted second 8-bit input data to thereby generate the first least significant bit value D_{1,L} to the eighth least significant bit value D_{8,L}, and transmit each of the first least significant bit value D_{1,L} to the eighth least significant bit value D_{8,L} through each of the first global I/O line GIO_1 to the eighth global I/O line GIO_8.

At the same time, each of the first sense amplifier SA_1 to the eighth sense amplifier SA_8 may latch each of the first most significant bit value D_{1,M} transmitted through the first global I/O line GIO_1 to the eighth most significant bit value D_{8,M} transmitted through the eighth global I/O line GIO_8.

In addition, in a third cycle tCAS_LSB, each of the first sense amplifier SA_1 to the eighth sense amplifier SA_8 may latch each of the first least significant bit value D_{1,L} transmitted through the first global I/O line GIO_1 to the eighth least significant bit value D_{8,L} transmitted through the eighth global I/O line GIO_8. Also, each of the first sense amplifier SA_1 to the eighth sense amplifier SA_8 may store each of the first specific level voltage to the eighth specific level voltage corresponding to each of the first 2-bit data to the eighth 2-bit data in each of the first memory cell C_1 to the eighth memory cell C_8, wherein the first 2-bit data is comprised of a latched first most significant bit value D_{1,M} and a latched first least significant bit value D_{1,L}, and wherein the eighth 2-bit data is comprised of a latched eighth most significant bit value D_{8,M} and a latched eighth least significant bit value D_{8,L}.

As seen above, the present disclosure has been explained by specific matters such as detailed components, limited embodiments, and drawings. They have been provided only to help more general understanding of the present disclosure. It, however, will be understood by those skilled in the art that various changes and modification may be made from the description without departing from the spirit and scope of the disclosure as defined in the following claims.

Accordingly, the thought of the present disclosure must not be confined to the explained embodiments, and the following patent claims as well as everything including variations equal or equivalent to the patent claims pertain to the category of the thought of the present disclosure.

What is claimed is:

1. A memory device comprising a plurality of memory cells storing n-bit data by an operation of a plurality of word lines and a plurality of bit lines, comprising:
at least one memory cell array including the plurality of word lines, the plurality of bit lines, and the plurality of memory cells;
a plurality of sense amplifiers, each of which is coupled to each of the plurality of bit lines, wherein each of the plurality of sense amplifiers is configured to, in a read mode, convert each of first specific level voltages stored in each of the plurality of memory cells into each of first n-bit data and output each of the first n-bit data, wherein each of first significant bit values of each of the first n-bit data is sequentially outputted, and wherein n is an integer of 2 or more, and, in a write mode, convert second n-bit data into second specific level voltages so as to store the second specific level voltages in each of the plurality of memory cells; and
at least one MUX/DEMUX, wherein each of k global I/O lines corresponding to a prefetch size is coupled to each of k sense amplifiers in each of sense amplifier groups, wherein the sense amplifier groups are obtained by grouping the plurality of sense amplifiers by k, wherein k is an integer of 1 or more, wherein the at least one MUX/DEMUX is configured to, in the read mode, multiplex each of the first significant bit values of each of the k sense amplifiers to output k-bit output data, and in the write mode, demultiplex each of k-bit input data into each of second significant bit values and thus apply each of the second significant bit values to each of the k sense amplifiers through each of the k global I/O lines.

2. The memory device of claim 1, wherein, (R) in the read mode, (R_1) in a (1_1)-st cycle, each of the k sense amplifiers, which is a first sense amplifier to a k-th sense amplifier, outputs a (1_1_1)-st significant bit value of a (1_1)-st n-bit data to a (1_k_1)-st significant bit value of a (1_k)-th n-bit data, wherein each of the (1_1_1)-st significant bit value to the (1_k_1)-st significant bit value corresponds to each of a (1_1)-st specific level voltage to a (1_k)-th specific level voltage stored in each of a first memory cell to a k-th memory cell corresponding to each of the first sense amplifier to the k-th sense amplifier, (R_2) in a (1_i)-th cycle, each of the first sense amplifier to the k-th sense amplifier outputs each of a (1_1_i)-th significant bit value of the (1_1)-th n-bit data to a (1_k_i)-th significant bit value of the (1_k)-th n-bit data, and the MUX/DEMUX multiplexes a (1_1_(i−1)-th significant bit value to a (1_k_(i−1)-th significant bit value transmitted through each of a first global I/O line to a k-th global I/O line and thus outputs a (i−1)-th k-bit output data comprised of the (1_1_(i−1)-th significant bit value to the (1_k_(i−1)-th significant bit value, wherein i is an integer increasing from 2 to n, (R_3) in a (1_(n+1))-th cycle, the MUX/DEMUX multiplexes a (1_1_n)-th significant bit value to a (1_k_n)-th significant bit value transmitted through each of the first global I/O line to the k-th global I/O line and thus outputs an n-th k-bit output data comprised of the (1_1_n)-th significant bit value to the (1_k_n)-th significant bit value,
wherein, (W) in the write mode, (W_1) in a (2_1)-st cycle, the MUX/DEMUX demultiplexes a first k-bit input data and thus outputs each of a (2_1_1)-st significant bit value to a (2_k_1)-st significant bit value through each of the first global I/O line to the k-th global I/O line, (W_2) in a (2_i)-th cycle, the MUX/DEMUX demultiplexes an i-th k-bit input data and thus outputs each of a (2_1_i)-th significant bit value to a (2_k_i)-th significant bit value through each of the first global I/O line to the k-th global I/O line, and each of the first sense amplifier to the k-th sense amplifier latches each of a (2_1_(i−1))-th significant bit value to a (2_k_(i−1)-th significant bit value transmitted through each of the first global I/O line to the k-th global I/O line, (W_3) in a (2_(n+1)-th cycle, each of the first sense amplifier to the k-th sense amplifier latches each of a (2_1_n)-th significant bit value to a (2_k_n)-th significant bit value transmitted through each of the first global I/O line to the k-th global I/O line, and stores each of a (2_1)-st specific level voltage to a (2_k)-th specific level voltage corresponding to each of a (2_1)-st n-bit data to a (2_k)-th n-bit data in each of the first memory cell to the k-th memory cell, wherein the (2_1)-st n-bit data is comprised of a latched (2_1_1)-st significant bit value to a latched (2_1_n)-th significant bit value, and wherein the (2_k)-th n-bit data is comprised of a latched (2_k_1)-st significant bit value to a latched (2_k_n)-th significant bit value.

3. The memory device of claim 1, wherein each of a first bit line to a k-th bit line coupled to each of the k sense amplifiers is located in a same memory cell array,
wherein each of the k sense amplifiers is coupled to each of the k global I/O lines coupled to one of the MUX/DEMUX.

4. The memory device of claim 1, wherein each of a first bit line to a k-th bit line coupled to each of the k sense amplifiers is located in a different memory cell array,
wherein each of the k sense amplifiers is coupled to each of the k global I/O lines of each of the MUX/DEMUX.

5. The memory device of claim 1, wherein each of the k sense amplifiers includes each of successive approximation register analog-to-digital converters that sequentially outputs each of the first significant bit values of each of the first n-bit data.

6. The memory device of claim 1, wherein each of the k sense amplifiers includes each of input ends into which each of the second significant bit values is inputted, each of selection switches that sequentially activates each of the input ends, and each of digital-to-analog converters that applies, to each of the plurality of bit lines, each of the second specific level voltages corresponding to each of the second significant bit values sequentially inputted through each of the selection switches.

7. The memory device of claim 1, wherein each of the k sense amplifiers refreshes each of k memory cells corresponding to each of the k sense amplifiers by using at least some of specific significant bit values among the first significant bit values.

8. The memory device of claim 7, wherein each of the k sense amplifiers is coupled to the k global I/O lines through each of k global switches,
wherein each of the k global switches is deactivated when each of the specific significant bit values are used to refresh each of the k memory cells.
